(19) United States
(12) Patent Application Publication
(10) Pub. No.: US 2026/0026117 A1
(43) Pub. Date: Jan. 22, 2026

(54) HIGH DYNAMIC RANGE PIXEL

(71) Applicant: STMicroelectronics International N.V., Geneva (CH)

(72) Inventors: Marios BARLAS, Grenoble (FR); Simone AUSILIO, Bientina (PI) (IT); Dominique GOLANSKI, Gieres (FR)

(73) Assignee: STMicroelectronics International N.V., Geneva (CH)

(21) Appl. No.: 19/240,866

(22) Filed: Jun. 17, 2025

(30) Foreign Application Priority Data
Jun. 19, 2024 (GR) 20240100454
Jul. 19, 2024 (FR) FR2407992

(51) Int. Cl. H10F 39/00; H10F 39/18; H10F 77/60

(52) U.S. Cl. CPC H10F 39/8033; H10F 39/182; H10F 77/60

(57) ABSTRACT

A pixel includes a photosensitive element having a surface intended to receive light and a filter above the surface of the photosensitive element. The filter includes patterns made of a phase-change material and heating elements defined in an electrically-conductive layer of the filter. A temperature of the heating elements determines a temperature of the phase-change material. A control circuit for the pixel controls a temperature of the heating elements to modify a state of the phase-change material and a transmission rate of the filter depends on the state of the phase-change material.

### PRIORITY CLAIM

This application claims the priority benefit of Greek Application for Patent No. 20240100454, filed on Jun. 19, 2024, and claims the priority benefit of French Application for Patent No. FR2407992, filed on Jul. 19, 2024, the contents of which are hereby incorporated by reference in their entireties to the maximum extent allowable by law.

### TECHNICAL FIELD

The present disclosure generally concerns electronic circuits and, more particularly, a high dynamic range (HDR) pixel and a light sensor comprising a plurality of high dynamic range pixels.

### BACKGROUND

A pixel is an element configured to convert light, received in an operating wavelength range of the pixel, into an output signal of the pixel, for example a current or a voltage, having a value representative of the amount of light received.

When a sensitive pixel operates in low light conditions, a small variation in the amount of received light results in a corresponding variation in the output signal of the pixel. However, a disadvantage of a sensitive pixel is that, when it operates in strong light conditions, the output signal of the pixel saturates and its value is no longer representative of the amount of light received in strong light conditions.

Conversely, a less sensitive pixel allows, when it operates in strong light conditions, for its output signal not to saturate and to be well representative of the amount of light received. However, when a less sensitive pixel operates in low light conditions, the amount of light received is not sufficient to cause a corresponding variation in the output signal of the pixel, and the light is not detected by the pixel in low light conditions.

To overcome the above disadvantages, there have been provided so-called high dynamic range pixels, that is, pixels enabling to obtain an output signal of the pixel which varies with the amount of light received, whether the pixel operates in low light conditions or in strong light conditions. As an example, a pixel is said to have a high dynamic range when its output signal varies substantially linearly over a dynamic range of at least 80 dB, preferably at least 90 dB. More preferably, a pixel is said to have a high dynamic range when its output signal varies substantially linearly over a dynamic range of at least 100 dB, preferably at least 115 dB.

However, these high dynamic range pixels have various disadvantages. For example, these pixels are more complex and/or more bulky to implement. For example, these pixels require specific processing circuits, more complex and/or expensive to implement.

There exists a need in the art for a high dynamic range pixel which overcomes all or part of the disadvantages of known high dynamic range pixels.

### SUMMARY

An embodiment provides a pixel, comprising: a photosensitive element; a filter over a surface of the photosensitive element intended to receive light; wherein the filter comprises: a plurality of identical patterns made of a phase-change material, and a plurality of heating elements defined in an electrically-conductive layer of the filter, the electrically-conductive layer being parallel to said surface intended to receive light and the heating elements being configured so that a temperature of the heating elements determines a temperature of the phase-change material of the patterns; and a circuit configured to control the temperature of the heating elements.

According to an embodiment, the filter is configured so that a transmission rate of the filter for light in an operating wavelength range depends on a state of the phase-change material.

According to an embodiment, the patterns are arranged periodically.

According to an embodiment, each pattern comprises two surfaces parallel to each other and to the electrically-conductive layer, the pattern extending from one to the other of said two surfaces and having a first one of said two surfaces which faces the electrically-conductive layer.

According to an embodiment, the filter comprises, for each pattern, a portion of an anti-reflective layer resting on top of and in contact with that of said two surfaces of the pattern which is intended to receive light.

According to an embodiment: the anti-reflective layer is made of nitride or tantalum oxide, for example of tantalum pentoxide, and the phase-change material is antimony trisulfide, antimony sulfide, germanium sulfide, or germanium telluride.

According to an embodiment, the filter further comprises, on the second side of the patterns, a thermally-conductive layer.

According to an embodiment, the thermally-conductive layer is made of a material transparent to operating wavelengths of the pixel, for example made of indium tin oxide.

According to an embodiment, the electrically-conductive layer is made of a material transparent to operating wavelengths of the pixel, for example made of indium tin oxide.

Another embodiment provides a light sensor comprising a plurality of pixels such as defined hereabove.

Another embodiment provides a method comprising: controlling, in a pixel comprising a photosensitive element and a filter above a surface of the photosensitive element intended to receive light, with a circuit of the pixel, a temperature of a plurality of heating elements defined in a layer of the filter which is electrically conductive and parallel to said surface intended to receive light, so as to change a state of a plurality of identical patterns made of a phase-change material.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows, in a simplified cross-section view, an embodiment of a high dynamic range pixel;

FIG. 2 shows, in a simplified perspective view, a detail of implementation of a filter of the pixel of FIG. 1;

FIG. 3 illustrates with curves the operation of the filter of the pixel of FIG. 1; and

FIG. 4 shows, schematically and in the form of blocks, an example of a sensor comprising a plurality of pixels of the type shown in FIG. 1.

### DETAILED DESCRIPTION

The same elements have been designated by the same references in the various figures. Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

There is here provided a pixel comprising a filter dynamically configurable so that the transmission rate of the filter, for light received in an operating wavelength range of the filter, is controllable, for example between at least one high transmission state for which the transmission rate is, for example, at least 80%, or even at least 90%, and a low transmission state for which the transmission rate is, for example, at most 20%, or even at most 10%.

Thus, the pixel may be provided to operate in low light conditions, the filter then being controlled to have a high transmission rate, and in strong light conditions, the filter then being controlled to have a low transmission rate, so that, preferably, the output signal of the pixel does not saturate.

More particularly, the provided filter comprises a plurality of patterns made of a phase-change material, and a plurality of heating elements configured so that a temperature of the heating elements determines a temperature of the phase-change material. Thus, when for an operating wavelength range of the pixel or of the filter, the transmission rate of the filter depends on the state of the phase-change material, the transmission rate of the filter may be controlled by modifying the state of the phase-change material, that is, by controlling the temperature of the heating elements.

An advantage of such a filter is that it is sufficient to provide it in a pixel configured to operate in dim (low) light conditions for this pixel to become a high dynamic range pixel. The obtained pixel is thus less complex, less bulky, and/or less expensive to implement than known high dynamic range pixels. In particular, the obtained pixel is, for example, less complex to implement in terms of a Complementary Metal Oxide Semiconductor (CMOS) manufacturing method. Further, the pixel thus obtained does not require complex, bulky, and/or expensive processing circuits, as is the case of known high dynamic range pixels, for example, known high dynamic range pixels configured to implement multiple-exposure time acquisitions.

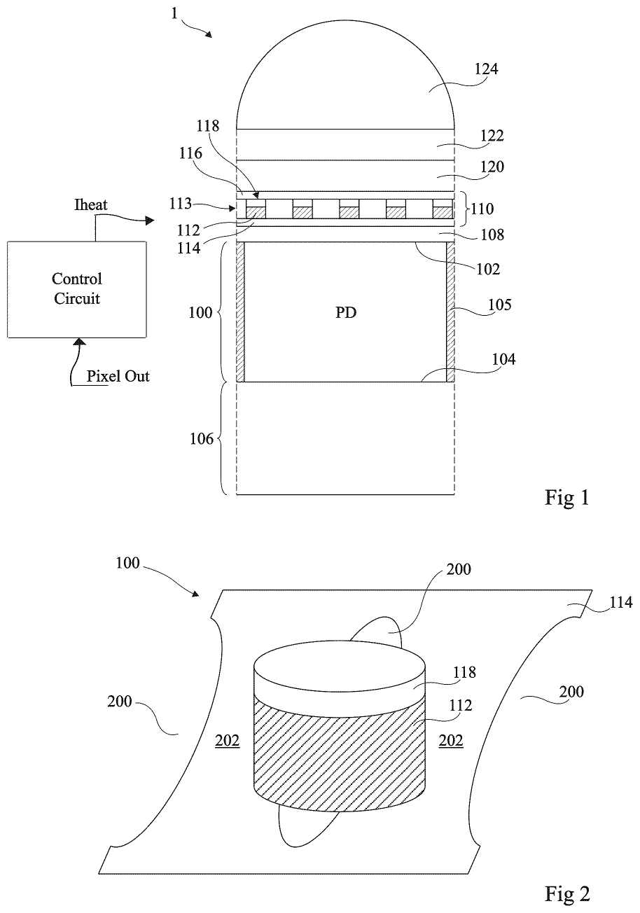

FIG. 1 shows, in a simplified cross-section view, an example of an embodiment of a pixel 1.

Pixel 1 comprises a photosensitive element PD. For example, photoconversion element PD corresponds to a portion of a semiconductor substrate 100. For example, photosensitive element PD extends from a back side 102 (upper surface in FIG. 1) to a front side 104 (lower surface in FIG. 1) of substrate 100.

Usually, electronic components (not explicitly shown in FIG. 1), such as for example transistors and/or horizontal or vertical transfer gates as is well-known to those skilled in the art, are arranged inside and/or on top of substrate 100, on its front side 104.

Usually, an interconnection structure 106, for example of BEOL (back end of line) type as is well-known to those skilled in the art, rests on the front side 104 of substrate 100 and comprises portions of electrically-conductive layers (not explicitly shown in FIG. 1) coupled together by electrically-conductive vias (not explicitly shown in FIG. 1) to electrically connect, to one another and/or to connection pads, electronic components arranged on front side 104.

In the example of FIG. 1, pixel 1 is illuminated from back side 102. In other words, pixel 1 is configured so that its photosensitive element PD receives light to be converted on the back side 102 of substrate 100. Still in other words, photosensitive element PD is configured to receive light via a surface of photosensitive element PD which is arranged on the back side 102 of substrate 100.

As an example, photosensitive element PD is laterally delimited by insulating structures 105, such as for example deep trench isolation (DTI) or capacitive deep trench isolation (CDTI) trenches.

The surface 102 of substrate 100, that is, the surface 102 of element PD in the example of FIG. 1, is coated, preferably, with a passivation layer 108 resting on top of and in contact with surface 102.

Pixel 1 further comprises a filter 110. Filter 110 is arranged above the surface 102 of element PD which is intended to receive light. Preferably, filter 110 faces the entire surface of element PD which is intended to receive light. As an example, filter 110 rests on passivation layer 108, for example in contact with passivation layer 108.

Filter 110 comprises a plurality of identical patterns 112. Patterns 112 are made of a phase-change material. For example, each pattern 112 comprises a first surface that is facing element PD and parallel to surface 102, a second surface parallel to the first surface, and extends from one to the other of these first and second surfaces. Patterns 112 are arranged in a dielectric layer 113. Although this is not shown in FIG. 1, as an example, each pattern has a cylindrical shape vertically extending from one to the other of the first and second surfaces, the base of the cylinder being, for example, circular or regularly polygonal. As an example of a regular polygonal base, the base of pattern 112 may be triangular, hexagonal, square, octagonal, decagonal, dodecagonal, etc.

Preferably, patterns 112 are organized periodically, for example in two mutually orthogonal directions parallel to surface 102. For example, the period of a grating formed by patterns 112 is determined by an operating wavelength range of pixel 1, for example by a wavelength range of filter 110.

Preferably, for an operating wavelength range of filter 110, patterns 112 and layer 113 form a fano-resonant filter at least for a given state, for example the crystalline state, of the phase-change material.

Filter 110 further comprises an electrically-conductive layer 114. Layer 114 is parallel to surface 102, or, in other words, extends parallel to surface 102. Although this is not visible in FIG. 1, heating elements are defined in layer 114. These heating elements are configured so that a temperature of the heating elements determines a temperature of the phase-change material of patterns 112, and thus the state, for example crystalline or amorphous, of the phase-change material.

Layer 114 is made of a material transparent in the operating wavelength range of filter 110. For example, layer 114 is made of a material transparent for the operating wavelengths of pixel 1. As an example, a layer is said to be made of a material transparent to a given wavelength when more than 80%, preferably more than 90%, of a light radiation at this wavelength is transmitted across the thickness of this layer.

In the example of FIG. 1, layer 114 is arranged between surface 102 and pattern 112. In other words, the surfaces of pattern 112 facing photosensitive element PD also face layer 114. In the example of FIG. 1, layer 114 rests on top of, and for example in contact with, passivation layer 108. In this case, each pattern 112 has its surface facing element PD which is, for example, in contact with layer 114, for example, with one or a plurality of the heating elements defined in layer 114.

In other, non-illustrated examples, layer 114 is arranged on the side of the surfaces of patterns 112 which do not face the surface 102 of element PD. In other words, in these other examples, patterns 112 are arranged between the surface of element PD which is intended to receive light and layer 114.

Further, the pixel 1 comprises a control circuit configured to control the temperature of the heating elements defined in layer 114. For example, the circuit is configured to control a value of a current Iheat flowing through layer 114, for example so that the higher the current flowing through layer 114, the higher the temperature of the heating elements.

According to an embodiment, the circuit controlling filter 110, that is, the temperature of the heating elements, is configured to control the filter based on the value of the output signal Pixel out (voltage or current) of the pixel. For example, when the output signal of the pixel exceeds a threshold and approaches a saturation value, the circuit is configured to control turn on of the filter 110 so as to decrease the transmission rate of the filter.

According to an embodiment, filter 110 comprises a thermally-conductive layer 116. Layer 116 is arranged on the side of the surfaces of patterns 112 which are opposite to the surfaces of the patterns facing layer 114, that is, on the side of the upper surfaces of patterns 112 in the example of FIG. 1 where the lower surfaces of patterns 112 face layer 114. Thus, in the example of FIG. 1, layer 116 is arranged above patterns 112.

Layer 116 is configured to dissipate heat from patterns 112. In other words, layer 116 is a heat sink for patterns 112. For example, layer 116 is made of a material transparent for the operating wavelengths of pixel 1. For example, layer 116 is made of a material transparent for the operating wavelengths of filter 110.

In alternative embodiments, layer 116 may be omitted.

According to an embodiment, the filter comprises, for each pattern 112, an anti-reflective layer portion 118 resting on top of and in contact with the surface of pattern 112 which is opposite to the surface of the pattern facing the surface 102 of element PD intended to receive light. In other words, the filter comprises, for each pattern 112, a portion of anti-reflective layer 118 resting on top of and in contact with the surface of pattern 112 which is intended to receive light. Thus, in the example of FIG. 1, each pattern 112 has its upper surface coated with a portion of anti-reflective layer 118. As an example, this anti-reflective layer portion implements an anti-reflective function in the operating wavelength range of filter 110.

As an example, for each pattern 112, the portion of anti-reflective layer 118 which covers pattern 112 has, in planes parallel to surface 102, the same dimensions as those of pattern 112.

As an example, in FIG. 1 where layer 114 is arranged between surface 102 and pattern 112, and where filter 110 comprises layer 116, the latter may be in contact with anti-reflective portions 118.

Usually, pixel 1 may comprise other elements resting on filter 110, on the side of filter 110 which is intended to receive light.

For example, as illustrated in FIG. 1, pixel 1 may comprise a dielectric layer 120 resting on top of, and for example in contact with, the surface of filter 110 which is intended to receive light. In the example of FIG. 1, this layer 120 rests on top of and in contact with layer 116.

For example, as illustrated in FIG. 1, pixel 1 may comprise, in addition to filter 110, a filter 122, for example a filter configured to give way (i.e., is transmissive) to visible light having a wavelength within a given range of visible wavelengths, for example a filter configured to give way to blue, green, or red visible light. In the example of FIG. 1, this filter 122, for example made of resin or, for example, an interferometric multilayer filter, rests on layer 120, for example in contact with layer 120.

For example, as illustrated in FIG. 1, pixel 1 may comprise a microlens 124 resting on the side of filter 110 which is intended to receive light. In the example of FIG. 1, microlens 124 rests on top of, and for example in contact with, filter 122.

As an example, filter 110 is configured to operate in a wavelength range belonging to the Near InfraRed (NIR) domain, near infrared corresponding to a wavelength range from, for example, 700 nm to 1 μm. For example, filter 110 is configured so that its transmission rate depends on the state of the phase-change material of its patterns 112 in a wavelength range from approximately 920 nm to approximately 945 nm, this range then corresponding to the operating wavelength range of the filter. In this case, the phase-change material is, for example, antimony trisulphide (Sb₂S₃), while the anti-reflective portions may, for example, be made of tantalum pentoxide (Ta₂O₅).

However, the phase-change material of patterns 112 and/or the material of anti-reflective portions 118 are not limited to the example given hereabove, and those skilled in the art will be capable of adapting these materials according to the operating wavelength range of filter 110. For example, those skilled in the art may select the phase-change material from among antimony trisulfide, antimony sulfide, germanium sulfide, or germanium telluride. For example, those skilled in the art may use other materials for anti-reflective portions 118, for example other tantalum oxide or nitride.

According to an embodiment, when filter 110 is configured to operate in a wavelength range belonging to the near-infrared or infrared range, filter 110 is further configured so that its visible light transmission rate is at least 50%, preferably at least 60%, regardless of the state of the phase-change material of patterns 112.

According to an embodiment, a method of controlling filter 110 comprises a control of the temperature of the heating elements of the filter, so as to modify the state of the phase-change material of the patterns 112 of the filter, that is, for example, so as to modify the state of the phase-change material between a crystalline state and an amorphous state. This then results in a change in the transmission rate of filter 110 in its operating wavelength range.

FIG. 2 shows, in a simplified perspective view, an example of a detail of implementation of the filter 110 of pixel 1 according to an embodiment. More particularly, FIG. 2 shows a portion of filter 110, layer 116 not being shown and the portion shown in FIG. 2 comprising only one of the patterns 112 of filter 110.

In this example, electrically-conductive layer 114 comprises openings 200 crossing layer 114 all throughout its thickness. The openings are, for example, arranged periodically in the two directions orthogonal to each other and parallel to the surface 102 of the photosensitive element. As an example, openings 200 have, in top view, a substantially circular or oval shape. Openings 200 define portions 202 of layer 114 which correspond to the heating elements of filter 110. For example, between each two openings 200, layer 114 comprises a heating element 202.

According to an embodiment, an array of heating elements 202 is defined in layer 114 by means of openings 200.

In this example, pattern 112 has a cylindrical shape with a circular base. Further, in this example, pattern 112 has a surface coated with a portion of anti-reflective layer 118.

As an example, each pattern 112 is arranged on a corresponding opening 200. Pattern 112 may extend over layer 114, and, more particularly over one or a plurality of heating elements 202. For example, when layer 114 comprises openings 200 of oval or elliptical shape and each pattern 112 is arranged on a corresponding opening 200, pattern 122 may further extend over layer 114 on either side of opening 200 taken widthwise (to the left and to the right of opening 200 in FIG. 2), or, in other words, pattern 112 may further extend over adjacent heating elements 202.

Those skilled in the art will be capable of providing other ways of implementing the heating elements 202 defined in layer 114. For example, conductive tracks having identical and constant cross-sections may be defined in layer 114, and each conductive track then forms a heating element 202.

Further, as previously pointed out, those skilled in the art will be capable of providing other shapes of patterns 112 than that illustrated in FIG. 2.

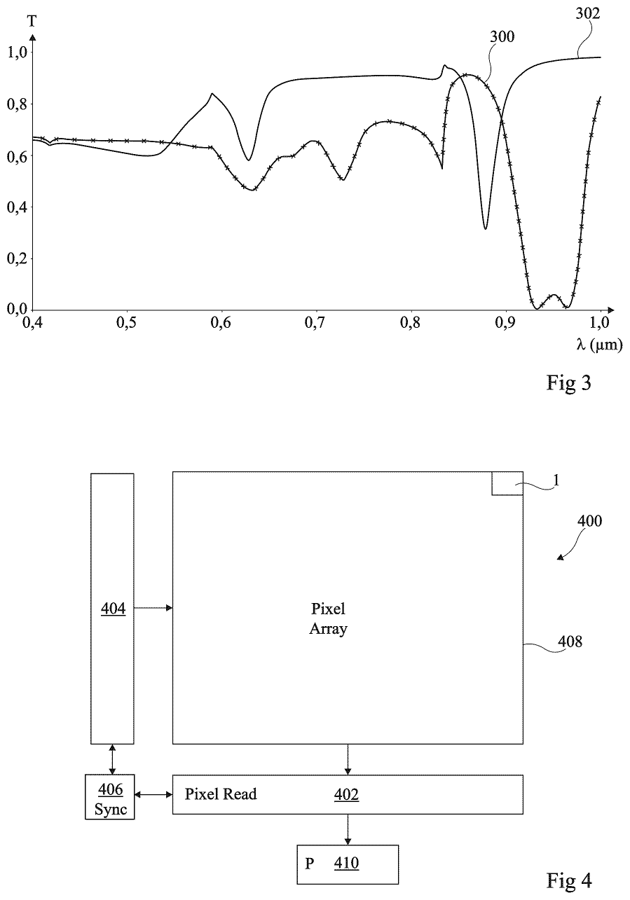

FIG. 3 shows with curves 300 and 302 the operation of an example of embodiment of the filter 110 of the pixel 1 of FIG. 1, when filter 110 is implemented as shown in FIG. 2.

More particularly, in this example, filter 110 is configured so that its transmission rate is controllable in the wavelength range from approximately 920 nm to approximately 945 nm. This wavelength range in which the transmission rate of the filter is controllable by modifying the state of the phase-change material of patterns 112 corresponds to the operating wavelength range of the filter.

In this example: the phase-change material of patterns 112 is antimony trisulfide (Sb₂S₃) and anti-reflective portions 118 are made of tantalum pentoxide (Ta₂O₅); electrically-conductive layer 114 is made of indium tin oxide (ITO); filter 110 comprises layer 116, and the latter is made of indium tin oxide; the layer 113 of the filter is made of silicon oxide; the thickness (or height) of each pattern 112 is 180 nm; the repetition period of patterns 112, in the first and second directions orthogonal to each other and parallel to surface 102, is 570 nm; and the radius of the circular base of patterns 112 is equal to 130 nm.

Curve 300, respectively 302, illustrates the normalized transmission rate T of filter 110 as a function of the wavelength (in μm) when the phase-change material is crystalline, respectively amorphous.

These curves show that filter 110 has, in its operating wavelength range, a transmission rate greater than 0.90 when the phase-change material is amorphous (curve 302) and a transmission rate smaller than 0.05 when the phase-change material is crystalline.

Although there has been described in relation with FIGS. 1 to 3 a back-side illuminated pixel 1 in which filter 110 is arranged on the back side of pixel 1, that is, on the back side 102 of substrate 100, those skilled in the art will be capable of adapting pixel 1 to a front-side illumination, filter 110 then being arranged on the front side of pixel 1, that is, on the front side 104 of the substrate, for example on interconnection structure 106, which will then be arranged between filter 110 and substrate 100.

Further, those skilled in the art will be capable of adapting the above description of pixel 1 in the case where pixel 1 comprises a single filter 110 to the case where pixel 1 comprises a stack of filters 110, for example two filters 110, each configured to have a controllable transmission rate in different wavelength ranges. Indeed, the provision of a plurality of stacked filters 110 with different operating wavelength ranges makes it possible to implement optical logic functions between the operating wavelength ranges of these stacked filters.

Further, although examples have been described where the state of the phase-change material is either crystalline or amorphous, those skilled in the art will be capable of providing a control of filter 110 enabling the phase-change material to be, in addition to the two above-mentioned states, in one or a plurality of intermediate states between the crystalline state and the amorphous state, each intermediate state then corresponding to a transmission rate having an intermediate value between maximum and minimum values corresponding to the crystalline and amorphous states.

Although a single pixel 1 has been described hereabove, according to an embodiment, a light sensor, for example an image sensor, comprising a plurality of pixels 1, for example organized in an array of pixels 1, is provided. In such a sensor, a circuit for controlling the filters 110 of pixels 1 is provided.

FIG. 4 shows, schematically and in the form of blocks, an example of a sensor 400 comprising a plurality of pixels 1.

Sensor 400 comprises a plurality of pixels 1, a single pixel 1 being shown and referenced in FIG. 4 so as not to overload the figure. In the example of sensor 400 of FIG. 4, pixels 1 are organized in an array 408 of pixels 1, array 408 comprising rows and columns of pixels 1.

Sensor 400 further comprises a circuit 404 for controlling pixels 1, for example a circuit 404 configured to control the rows of pixels 1. For example, circuit 404 is configured to control a reading of the rows of pixels one after the other, all the pixels in a row being read simultaneously.

Sensor 400 further comprises a circuit 402 for reading out pixels 1. For example, circuit 402 is configured to receive the output signals of the pixels 1 being read from, for example the output signals of all the pixels in a row being read from.

As an example, sensor 400 comprises a processing (P) circuit 410. Circuit 410 receives signals from circuit 402, these signals corresponding to the output values of the pixels read from. For example, circuit 402 is configured to implement an analog-to-digital conversion of the pixel output signals and/or correlated double sampling operations, etc., and to deliver the resulting signals to circuit 410. Circuit 410 is, for example, configured to reconstruct an image of a scene captured by sensor 400, from the signals that it receives from circuit 402.

As an example, sensor 400 may comprise a circuit (Sync) 406 enabling to synchronize circuits 406 and 402.

The implementation of a sensor comprising a plurality of pixels 1 is not limited to the example described hereabove in relation with FIG. 4.

Although the pixel 1 described hereabove has been presented as a pixel with a high dynamic range, the pixel 1 comprising filter 110 may also be used by taking advantage of the benefits provided by filter 110 in other contexts. For example, pixel 1 may be used as a pixel of a time-of-flight (ToF) sensor, for example a direct time-of-flight sensor (dToF) or an indirect time-of-flight sensor (iTof). Further, although this has not been specified up to here, the photoconversion element PD of pixel 1 may be, for example, a conventional photodiode, a pinned photodiode, a single photon avalanche diode (SPAD), or any other photoconversion element commonly used in a pixel. For example, element PD may be a SPAD in the case where pixel 1 is used in a ToF sensor.

Further, one or a plurality of pixels 1 may be used in various fields and applications.

For example, one or a plurality of pixels 1 may be used in electronic systems on-board vehicles. For example, a sensor comprising one or a plurality of pixels 1 may be provided to implement radar functions, for example to obtain distance maps between the vehicle and elements surrounding it. For example, a sensor comprising one or a plurality of pixels 1 may be provided to obtain images of the vehicle environment or of the interior of the vehicle cabin. For example, a sensor comprising one or a plurality of pixels 1 may be used to deliver input data to driver assistance systems or automatic drive systems.

As other examples, one or a plurality of pixels 1 may be provided in personal electronic systems such as cell phones or devices of Internet of Things (IoT) type. For example, an image sensor comprising one or a plurality of pixels 1 may be provided in a cell phone, for example in a camera of the phone or in a facial recognition device of the phone. For example, an image sensor comprising one or a plurality of pixels 1 may be provided in an IoT device to implement functionalities of depth mapping of the environment of the device or of detection of the presence of an object in the field of the sensor.

As other examples, one or a plurality of pixels 1 may be provided in electronic systems embedded in industrial devices. For example, an image sensor comprising one or a plurality of pixels 1 may be provided in a robot to provide three- and/or two-dimensional images enabling the robot to know its environment in order to implement a specific function.

As other examples, one or a plurality of pixels 1 may be provided in autonomous robotic systems. For example, an image sensor comprising one or a plurality of pixels 1 may be provided in an autonomous robot, for example an industrial or domestic vacuum cleaner, to provide three- and/or two-dimensional images enabling the robot to know its environment in order to implement a specific function.

Various embodiments and variants have been described. Those skilled in the art will understand that certain features of these various embodiments and variants could be combined, and other variants will become apparent to those skilled in the art.

Finally, the practical implementation of the described embodiments and variants is within the abilities of those skilled in the art, based on the functional indications given hereabove.

1. A pixel, comprising:
a photosensitive element having a surface configured to receive light;
a filter over the surface of the photosensitive element;
wherein the filter comprises:
a plurality of identical patterns made of a phase-change material; and
a plurality of heating elements defined in an electrically-conductive layer of the filter, the electrically-conductive layer extending parallel to said surface;
a circuit configured to control a temperature of the plurality of heating elements;
wherein the temperature of the plurality of heating elements determines a temperature of the phase-change material of the identical patterns; and
wherein a transmission rate of the filter depends on a state of the phase-change material.

2. The pixel according to claim 1, wherein the filter is configured so that a transmission rate of the filter for light in an operating wavelength range depends on the state of the phase-change material.

3. The pixel according to claim 1, wherein the identical patterns are arranged periodically.

4. The pixel according to claim 1, wherein each identical pattern comprises two surfaces parallel to each other and to the electrically-conductive layer, the identical pattern extending from one to the other of said two surfaces and having a first one of said two surfaces which faces the electrically-conductive layer.

5. The pixel according to claim 4, wherein the filter comprises, for each identical pattern, a portion of anti-reflective layer resting on top and in contact with that of said two surfaces of the identical pattern which is intended to receive light.

6. The pixel according to claim 5, wherein:
the anti-reflective layer is made of a material selected from the group consisting of nitride, oxide tantalum, or tantalum pentoxide, and the phase-change material is made of a material selected from the group consisting of antimony trisulphide, antimony sulphide, germanium sulphide, or germanium telluride.

7. The pixel according to claim 4, wherein the filter further comprises, on a side of second surfaces of the identical patterns, a thermally-conductive layer.

8. The pixel according to claim 7, wherein the thermally-conductive layer is made of a material transparent to operating wavelengths of the pixel.

9. The pixel according to claim 1, wherein the electrically-conductive layer is made of a material transparent to operating wavelengths of the pixel.

10. The pixel according to claim 1, wherein the heating elements include openings, and the identical patterns made of the phase-change material are disposed over the openings.

11. A light sensor, comprising a plurality of pixels, wherein each pixel is the pixel according to claim 1.

12. A method for operating a pixel comprising a photosensitive element and a filter above a surface of the photosensitive element intended to receive light, the method comprising:
controlling, in the pixel, a temperature of a plurality of heating elements defined in a layer of the filter which is electrically conductive and parallel to said surface intended to receive light, so as to change a state of a plurality of identical patterns made of a phase-change material and a transmission rate of the filter depends on the state.
